(19) United States
(12) Patent Application Publication
(10) Pub. No.: US 2009/0301563 A1
(43) Pub. Date: Dec. 10, 2009

(54) SELF-CLEANING COATINGS APPLIED TO SOLAR THERMAL DEVICES

(76) Inventors: Alan J. McMaster, Maumee, OH (US); Dean M. Giolando, Toledo, OH (US)

Correspondence Address: FRASER CLEMENS MARTIN & MILLER LLC, 28366 KENSINGTON LANE, PERRYSBURG, OH, 43551, US

(21) Appl. No.: 12/541,308

(22) Filed: Aug. 14, 2009

Related U.S. Application Data
(62) Division of application No. 11/545,298, filed on Oct. 10, 2006.
(60) Provisional application No. 60/775,021, filed on Feb. 17, 2006.
(60) Provisional application No. 60/750,027, filed on Dec. 13, 2005.

(51) Int. Cl. H01L 31/00; B05D 5/12

(52) U.S. Cl. 136/256; 427/74

(57) ABSTRACT

A solar device and a process for preparing a self-cleaning coating on the solar device is disclosed, the process comprises providing a coating composition, adding to the coating composition nanocrystals of a photoactive material, and applying the mixture of coating composition and photoactive material to a surface of a substrate at an elevated temperature, to deposit a self-cleaning coating on the surface of the substrate. The solar device comprises a solar energy conversion device, including a transparent substrate, and a self-cleaning coating adhered to a surface of the substrate.

### CROSS-REFERENCE TO RELATED APPLICATION

This application is a divisional application of U.S. patent application Ser. No. 11/545,298 filed Dec. 7, 2006 entitled “SELF-CLEANING COATINGS APPLIED TO SOLAR THERMAL DEVICES” which claims the benefit of U.S. Provisional Application Ser. No. 60/775,021 filed Feb. 17, 2006 entitled “SELF-CLEANING COATINGS APPLIED TO SOLAR THERMAL DEVICES” and U.S. Provisional Application Ser. No. 60/750,027 filed Dec. 13, 2005 entitled “PROCESS FOR PREPARING A SELF-CLEANING COATING”.

### FIELD OF THE INVENTION

The present invention relates generally to self-cleaning coatings which may be applied to solar thermal devices. More particularly, the invention is directed to methods that may be used to apply a coating that effectively sheds dirt and other residue that otherwise could result from exposure to the atmosphere, and the application of such transparent, generally abrasion-resistant, self-cleaning coatings to solar fluid heaters, solar energy collectors, and the like.

### BACKGROUND OF THE INVENTION

Coated surfaces that are exposed to outdoor elements typically become soiled by dirt and air born particles that deposit onto the coating due to wind, precipitation, and the like. These deposits often degrade the performance of the coating. For example, coated windows or exterior mirrored surfaces often become coated over time with soil, reducing the transmission of light through the window or the reflective capability of the mirrored surface. This necessitates costly and labor intensive cleaning regiments, to keep the windows or mirrored surfaces at peak performance.

There are two principal types of devices wherein sunlight is converted to a usable form of energy. The first is a solar thermal fluid heater. The second is a solar energy collector that concentrates solar thermal energy for power generation. In both cases, the devices are exposed to the outdoor environment where they become coated with grime and dirt, which leads to the scatter of sunlight and the consequential loss of efficiency for the solar thermal devices.

It would be desirable to prepare solar thermal devices, as well as other devices exposed to the elements, that include self-cleaning coatings that resist the buildup of grime and dirt on their active surfaces during use.

### SUMMARY OF THE INVENTION

Accordant with one embodiment of the present invention, a process for preparing a self-cleaning coated substrate has surprisingly been discovered. The process comprises the steps of providing a coating composition, adding to the coating composition nanocrystals of photoactive material, and applying the mixture of coating composition and photoactive material to a surface of a substrate at an elevated temperature, to deposit a self-cleaning coating on the surface of the substrate

Also contemplated as an embodiment of the present invention is an improved solar thermal device that resists contamination by dirt and grime. It comprises a solar energy conversion device, including a transparent substrate, and a self-cleaning coating adhered to a surface of the substrate.

The coatings, processes, and solar thermal devices according to the present invention are particularly useful for making devices for converting solar energy into heat energy for the heating of buildings, for electrical power generation, and the like.

### BRIEF DESCRIPTION OF THE DRAWINGS

Exemplary features that are characteristic of the present invention are set forth with particularity in the appended Claims. Exemplary embodiments of the invention, as to structure and method of manufacture and use, will best be understood from the accompanying description of specific embodiments when read in conjunction with the Drawings, in which:

FIG. 1 is a schematic representation of a solar thermal fluid heater assembly according to an embodiment of the present invention;

FIG. 2 is a schematic representation of a solar energy collector assembly according to an embodiment of the present invention;

FIG. 3 is a schematic representation of a photovoltaic device according to an embodiment of the present invention;

FIG. 4 is a schematic representation of a solar thermal collector assembly according to an embodiment of the present invention; and

FIG. 5 is a schematic representation of a solar energy concentrator assembly according to an embodiment of the present invention.

### DETAILED DESCRIPTION OF EXEMPLARY EMBODIMENTS

A process for preparing a self-cleaning coated substrate according to the present invention comprises the steps of providing a coating composition, adding to the coating composition nanocrystals of photoactive material, and applying the mixture of coating composition and photoactive material to a surface of a substrate at an elevated temperatures to deposit a self-cleaning coating on the surface of the substrate.

The coating composition may comprise conventional coating precursors such as, by way of example but not limitation, Al(OPr)₃, Ti(OPr)₄, Zr(OPr)₄, Si(OEt)₄, Sn(OBu)₄, SnCl₄, SnBu₂O/acetate, Fe(OEt)₂, Mg(OEt)₂, CaO, and the like, as well as mixtures thereof.

Nanocrystals of a photoactive material are then added and mixed with the coating composition. The photoactive material may comprise nanocrystals of TiO₂ WO₃ Fe₂O₃ or CuO materials.

The mixture of coating composition and photoactive material may be applied to the substrate in a flowing vapor stream as a chemical vapor deposition (CVD) precursor, or may be applied in a solution by spraying, pouring, roll coating, etc. Convenient solvents for application as a solution may comprise water or hydrocarbon fluids, or mixtures thereof.

The mixture is applied to a surface of a substrate. The substrate may comprise glass, ceramic, metal, plastic, fiberglass, or any other substrate upon which coatings are conventionally applied by high-temperature processes.

The mixture is applied to the substrate at an elevated temperature, generally between about 80° C. and about 700° C. This may be accomplished by transporting the mixture in a carrier gas to the hot surface of the substrate in a CVD process, by applying a film of the mixture to the substrate which is then placed in a heating chamber, or by any other conventional method for applying the mixture to a surface of the substrate at an elevated temperature in order to deposit a self-cleaning coating onto the surface of the substrate.

The presence of the nanocrystals at the surface of the substrate causes the surface to be self-cleaning; viz, to shed dirt and other atmospheric residue.

In the case of a solar thermal fluid heater, a self-cleaning layer may be deposited on a substrate such as glass or plastic. Behind the substrate there may be placed a solar thermal fluid heater, such as a water heater.

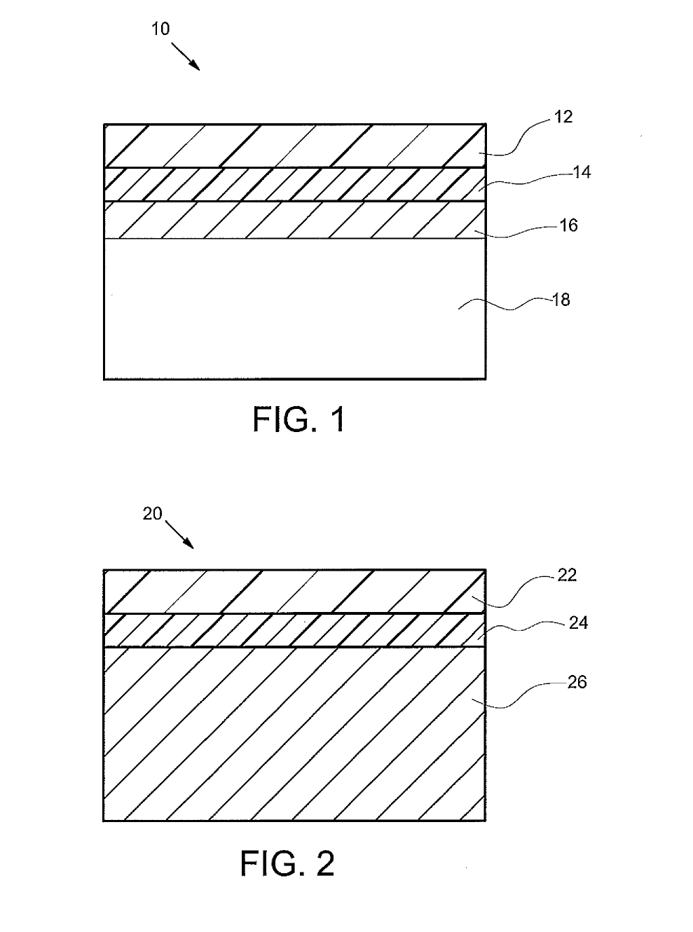

FIG. 1 illustrates a solar thermal fluid heater assembly 10, according to an embodiment of the present invention. It comprises a self-cleaning layer 12 adhered to a substrate 14. A heat reflector 16 may conveniently be placed between the substrate 14 and the solar thermal fluid heater 18. The heat reflector 16 is preferably thin enough to reduce losses due to sunlight reflection, and more preferably, can have an anti-reflecting coating.

The solar thermal fluid heater has flowing through it a fluid that is capable of transporting solar energy. The heat reflector acts to trap the heat, thus heating the fluid faster and to a higher temperature. This device may provide heated fluid, even when the outdoor temperature falls below 60 degrees Fahrenheit. Accordingly, such a device could provide year-round heating for a building. Because the efficiency over time of the inventive solar thermal fluid heater is greater than that of a conventional unit, the inventive heater could be smaller and still provide adequate heating; an advantage where space is at a premium such as in a crowded city environment.

In the case of a solar energy collector, a reflective material and an absorber material may be coated with a self-cleaning layer. Given that sunlight may be scattered at three locations before being absorbed and converted to a usable form of heat, power losses without the inventive self-cleaning layer could be significant.

FIG. 2 illustrates a solar energy collector assembly 20, according to an alternative embodiment of the present invention. It comprises a self-cleaning coating 22 adhered to a transparent, protective layer 24 which is adhered to a reflector 26.

The inventive structure is advantageous for trough technology used to heat a fluid to temperatures higher than 100 degrees Centigrade, which hot fluid may then be used to generate electricity. Current solar energy collector fields are oversized due to losses resulting from the buildup of grime and dirt on their active surfaces. By keeping the reflectors and absorbers in a clean state, the collector field can be smaller (i.e., fewer reflector elements will be needed) and a significant expense will be eliminated. This will result in a reduction in the cost for building solar thermal power plants, and will result in significant reductions in the costs of operating and maintaining electrical generating power plants.

In addition to direct electricity generation, these devices (with reflectors and absorbers coated with a self-cleaning layer) can be used to provide a hot fluid, such as water. Either a fluid is heated by sunlight, which then is used to heat the water supply, or the water supply flows through the solar thermal power device and is directly heated.

One major application could be the desalination of ocean water, to produce potable water. Ocean water could be directed through the solar thermal device and converted to a mixture of steam and salts. This mixture could be separated, preferably with a cyclone precipitator, and the gaseous water vapor transported to a condenser where liquid water is collected, preferably at an elevated position to render distribution easier. This would be made feasible due to the increased efficiency of an inventive solar thermal device according to an embodiment of the present invention, as the surfaces would be maintained in a clean state.

Examples of self-cleaning coatings which may be applied to substrates for the manufacture of solar thermal devices include, but are not necessarily limited to, consecutive layers of TiO₂ and WO₃, Fe₂O₃ and TiO₂, TiO₂ and WO₃, Al₂O₃ and TiO₂, and the like. Likewise, these materials individually may act as self-cleaning coatings. Additionally, those coatings set forth above, which contain nanocrystals, are also examples of the self-cleaning coatings that may be applied to solar thermal devices. Such coatings may be applied to the substrates or solar thermal devices by conventional methods.

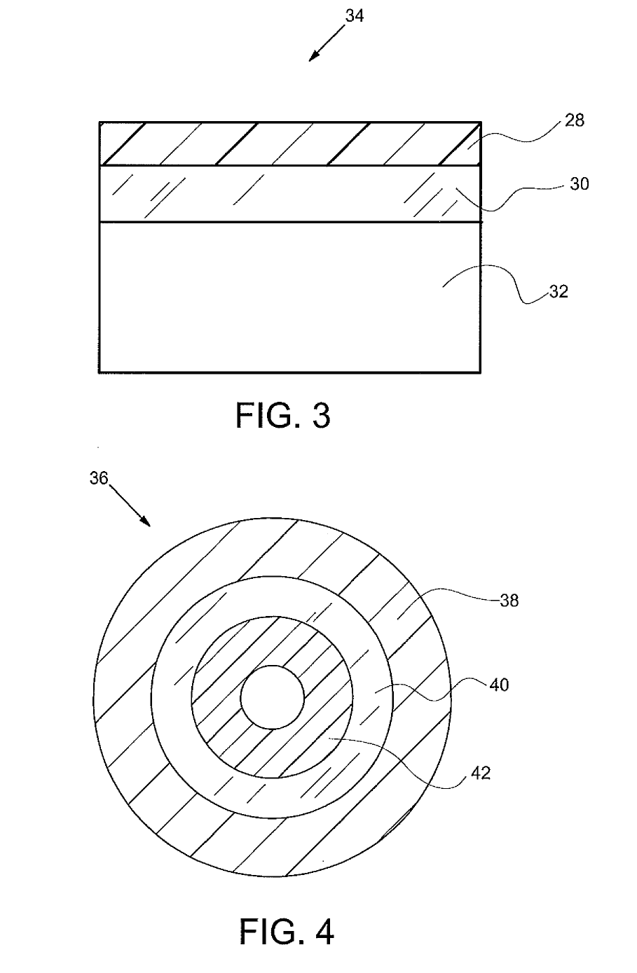

Moreover, the inventive self-cleaning coatings may be applied to other renewable energy conversion devices. For example, FIG. 3 illustrates one embodiment of the use of a self-cleaning coating 28 on a transparent substrate 30 of a photovoltaic material 32 in a photovoltaic device 34.

FIG. 4 illustrates an embodiment of a tubular solar thermal collector assembly 36, comprising a self-cleaning coating 38 adhered to a transparent substrate 40 having an emissive coating 42 on the interior surface thereof. The emissive coating 42 has a thickness optimized to allow a maximum amount of sunlight to pass, which is aided with an anti-reflecting coating.

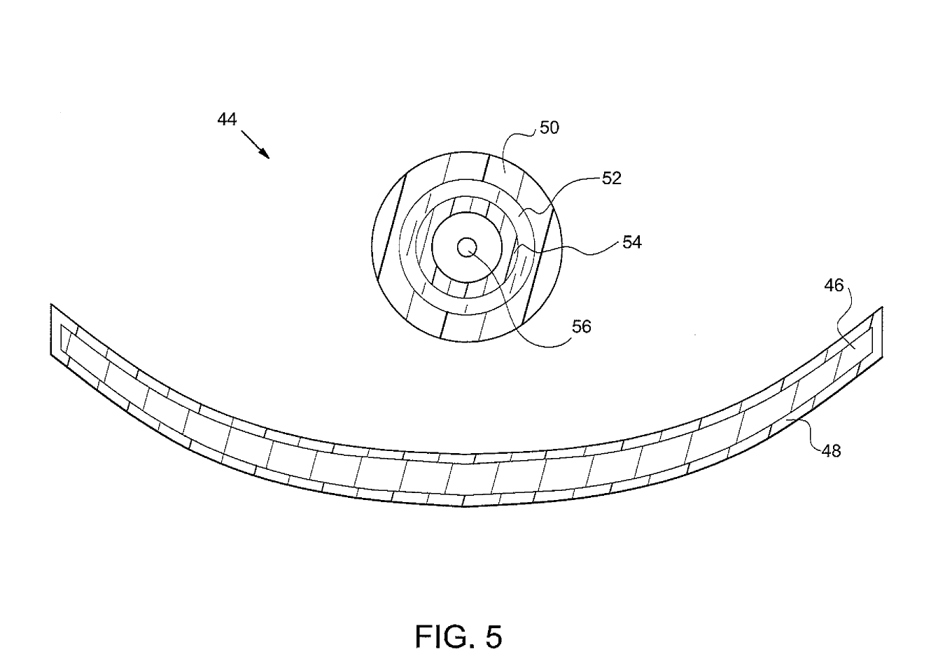

FIG. 5 illustrates an embodiment of a solar energy concentrator assembly 44. A first element comprises a reflector 46 coated with a self-cleaning layer 48. A second element comprises a self-cleaning coating 50 adhered to a transparent substrate 52, having an emissive coating 54 on the interior surface thereof, and an absorber material 56 at the center thereof.

Finally, the inventive self-cleaning coating may be applied to the exposed surfaces of a wind generator turbine blade. This would effectively keep the turbine blade cleaner and allow for lower wind resistance and increased power generation.

### EXAMPLE I

To a liter volumetric flask is added Al(OPr)₃ and concentrated HCl. A white solid forms which dissolves completely on adding water. About 50 mg of TiO₂ nanocrystals is added to the flask, which is sonicated for 5 min. Water is added to give 1 liter of slurry/solution. The solution is applied to a glass substrate, heated to 270° C. for 15 min, then cooled to room temperature. When washed, the % transmission is identical to that of the glass sample. An organic dye is applied to the coated surface, illuminated with a UV lamp for about 10 h and the intensity of the dye is reduced to about ½ of the initial value. A sample with a dot of dye is placed outside in sunshine and the intensity of the dye is reduced. Dye on bare glass is run at the same time, but there is no decrease in the intensity.

The same result is obtained on replacing Al(OPr)₃ with Ti(OPr)₄, Zr(OPr)₄, Si(OEt)₄, Sn(OBu)₄, SnCl₄, SnBu₂O/acetate, Fe(OEt)₂, Mg(OEt)₂, or CaO. In all cases, the self-cleaning property is obtained.

The concentration of the nanocrystals influences the rate of self-cleaning; using a higher concentration leads to more active films, With a high concentration of nanocrystals, the dye completely disappears oil illumination.

Mixtures of the above solutions can also be used. A solution of a Zr(OPr)₄ is added to the Ti(OPr)₄ solution to increase film growth of TiO₂ nanocrystalline films.

The films provide self-cleaning properties as-deposited, and also after heat treatment of 550° C.; hence substrates can be coated and then tempered.

The solutions can be applied by spray (either onto a heated substrate or onto a room temperature substrate that is then heated), dip-coated, spin coated or brushed/wiped.

### EXAMPLE II

Photoactive nanocrystals can be entrained in the gas phase, using a carrier gas to move the nanocrystals, and added to the vapor stream of a chemical vapor deposition process. A carrier gas containing TiO₂ nanocrystals is brought into contact with a gas stream containing SnCl₄ and a fluorinated ester. The gas/vapor mixture is brought in contact with a heated glass substrate whereupon a film of SnO₂:F forms. A dot of dye decreases in intensity of illumination, while a film of SnO₂:F formed under similar conditions (but without the photoactive nanocrystals) does not show self-cleaning properties. This could be a useful procedure for the last step of a CVD process for forming a multi-layer anti-reflective coating; which will result in the formation of a self-cleaning anti-reflective coating.

Potentially, the photoactive nanocrystals could be a component of sputtering targets. On sputter deposition, a film is obtainable having embedded photoactive nanocrystals, and thereby possess self-cleaning properties, Similarly, evaporation sources could have photoactive nanocrystals, which co-evaporate and become embedded in the film.

### EXAMPLE III

To a flask is added CaO, trifluoroacetic acid, HOPr and cyclohexanol. Nanocrystals of TiO₂ are added and the solution/slurry sonicated for 5 min. The solution is applied to a glass substrate heated to 300° C. After washing with water the % transmission is found to be about 94%, while the bare glass prior to coating has a % transmission of about 89%. A dot of dye is applied to the coating, which after illumination is reduced in intensity. The coating provides both anti-reflective and self-cleaning properties to the substrate.

Other examples are obtained with Mg, Si, and Al. Mixtures can also lead to self-cleaning anti-reflective coatings. For example, a 1:1 mixture of the Al and Si reagents detailed above provides a film on glass having a 91% transmission, while the bare glass has a 89% transmission, and excellent self-cleaning properties.

The photoactive nanocrystalline material can be used to create air pockets and pores in the film, which leads to the formation of anti-reflective coatings. TiO₂ nanocrystals can be added to a solution of Al(OPr)₃, HCl, high boiling organic (such as alcohol, surfactant, glycol, and others). On coating a substrate, the film contains the organic in the film. Subsequent illumination leads to decomposition of the organic and the creation of a self-cleaning anti-reflective coating.

This could assist in obtaining self-cleaning, anti-reflective coatings at low temperature. This would be useful for imparting these film properties on objects that cannot be heated to higher temperatures, or for objects already assembled and “in the field”. For example, coating the sunny-side of a photovoltaic device that is fully assembled requires the film formation to occur below 200° C., and preferrably at about 125° C., which is the temperature a photovoltaic device reaches in the field. This invention provides a means of applying a solution to the device at low temperature, then forming a self-cleaning, anti-reflective coating upon heating to a temperature that does not damage the coated object.

A hard, protective, self-cleaning layer of Al₂O₃ with TiO₂ nanocrystals, or ZrO₂ with TiO₂ nanocrystals, can be applied to anti-reflective coatings without reducing the anti-reflective property.

### EXAMPLE IV

To a flask is added polyimide solution and nanocrystals of TiO₂, and the mixture sonicated for 5 min. The solution is applied to a glass substrate, and rolled to a thin layer. The sample is placed in an over at 85° C. for three hours. The % transmission of the polymer is similar to tile % transmission of the glass substrate prior to being coated, except for polymer absorbance at about 390 nm. Dye applied to the polymer, decreases in intensity on illumination. The polymer can be used directly, or cured at higher temperatures tinder an inert atmosphere. When submerged tinder water, the polymer is easily removed from the glass substrate

Since the polyimide polymer has a high refractive index (circa 1.7), it is possible to impart self-cleaning/anti-reflective properties to the polymer surface. For example applying a thin layer of SiO₂ to the polymer surface yields a coating with a 92% transmission, while the polymer had an 89% transmission prior to being coated. This example is on only one side of the polymer. Potentially a higher % transmission would be obtained if the polymer were removed, and a self-cleaning/anti-reflective coating applied to the exposed polymer surface. This would be beneficial for the manufacture of lightweight photovoltaic devices.

Photoactive nanocrystals can be added to other plastic/polymer materials (such as polycarbonates and fiberglass) to provide a self-cleaning material. This could have a wide range of applications; such as for keeping the blades of an electricity-generating windmill clean, which would reduce drag losses and lead to increase in efficiency.

Photoactive nanocrystals can be added to latex polymer (a component of house paint), or to enamels (a component of automobile paint), or to other such coatings, to render the object coated with self-cleaning properties.

Photoactive nanocrystals other than TiO₂ can be used. While TiO₂ is attractive due to availability and cost, its self-cleaning property is due to absorption of UV light, and there may exist applications where absorption of visible light is more useful. In such cases, nanocrystals of other photoactive materials, such as iron oxide, tungsten oxide, or other materials, can be used. Also, TiO₂ nanocrystals can be doped to increase their absorbance in the visible region of the spectrum.

The commercial value is quite large because there is a reasonable expectation that the cost of manufacturing of renewable energy devices, such as, for example, photovoltaic modules, solar thermal devices, and wind generation, can be dramatically reduced.

Also, the invention could be used in the replacement glass market, to bring self-cleaning glass to the household. The inventive coating could be applied as a finishing coat to provide a self-cleaning property.

The coating, according to the present invention, can be put on a polished metal surface to fabricate an abrasion resistant self-cleaning mirror, which would have value in solar thermal power plants.

Photoactive nanocrystals can also be entrained in a carrier gas and contacted with the surface of glass that is hot enough to be soft. The objective is to imbed the photoactive particles in the surface of the glass. This would be useful in a float line where sand is melted and drawn into sheets of glass. The photoactive particles could be incorporated into the surface of the glass sheets as the glass sheets are fabricated. In addition, a coating of porous SiO2 containing nanocrystals of photoactive material can be heated to the point of melting the SiO2 to the glass surface thereby producing a glass surface with photoactive material on the surface.

Photoactive nanocrystals can be entrained in a carrier gas used in any chemical vapor deposition procedure to imbed the photoactive particles into the film produced by the CVD procedure, which would be most useful for a float line manufacturing glass sheets.

The invention is more easily comprehended by reference to specific embodiments disclosed herein, which are representative of the invention. It must be understood, however, that these embodiments are provided only for the purpose of illustration, and that the invention may be practiced otherwise than as specifically illustrated without departing from it s spirit and scope.

What is claimed is:

1. A solar device, comprising:
a solar energy conversion device, including a transparent substrate; and
a self-cleaning coating adhered to at least a portion of a surface of the substrate.

2. The solar device according to claim 1, wherein the solar energy conversion device is one of a solar energy collector for heating a fluid or a solar energy collector for generating electricity.

3. The solar device according to claim 2, wherein the solar energy collector includes a reflector.

4. The solar device according to claim 1, wherein the transparent substrate comprises at least one of glass, ceramic, or plastic.

5. The solar device according to claim 4, wherein the transparent substrate comprises glass.

6. The solar device according to claim 1, wherein the self-cleaning coating comprises at least one of an oxide of aluminum, titanium, zirconium, silicon, tin, iron, magnesium, calcium, or tungsten.

7. The solar device according to claim 1, wherein the self-cleaning coating comprises nanocrystals of a photoactive material.

8. The solar device according to claim 7, wherein the photoactive material comprises at least one of TiO₂, WO3, Fe₂O₃, and CuO.

9. The solar device according to claim 1, including a self-cleaning coating prepared by the process of claim 1.

10. The solar device according to claim 1, including a self-cleaning coating prepared by the process of claim 6.

11. A self-cleaning coated substrate prepared by the process of:
providing a coating composition;
adding to the coating composition nanocrystals of a photoactive material; and
applying the mixture of coating composition and photoactive material to a surface of a substrate, wherein one of a) the substrate is provided at an elevated temperature prior to the application of the mixture, and b) the mixture is subjected to an elevated temperature following the application of the mixture, to deposit a self-cleaning coating on the surface of the substrate.

12. A self-cleaning coated substrate prepared by the process of:
providing a coating composition, comprising at least one of Al(OPr)₃, Ti(OPr)₄, Zr(OPr)₄, Si(OEt)₄, Sn(OBu)₄, SnCl₄, SnBu₂O/acetate, Fe(OEt)₂, Mg(OEt)₂, or CaO;
adding to the coating composition nanocrystals of a photoactive material, comprising at least one of TiO₂, WO₃, Fe₂O₃, and CuO; and
applying the mixture of coating composition and photoactive material to a surface of a substrate, comprising at least one of glass, ceramic, metal, or plastic, wherein one of a) the substrate is provided at an elevated temperature from about 80° C. to about 700° C. prior to the application of the mixture, and b) the mixture is subjected to an elevated temperature from about 80° C. to about 700° C. following the application of the mixture, to deposit a self-cleaning coating on the surface of the substrate.

13. A renewable energy conversion device, including a self-cleaning coating prepared by the process of:
providing a coating composition;
adding nanocrystals of a photoactive material to the coating composition; and
applying the mixture of coating composition and photoactive material to a surface of a substrate, wherein one of a) the substrate is provided at an elevated temperature prior to the application of the mixture, and b) the mixture is subjected to an elevated temperature following the application of the mixture, to deposit a self-cleaning coating on the surface of the substrate.

14. The renewable energy conversion device of claim 13, wherein the device is one of a solar thermal device and a photovoltaic device.

15. A renewable energy conversion device, including a self-cleaning coating prepared by the process of:
providing a coating composition, comprising at least one of Al(OPr)₃, Ti(OPr)₄, Zr(OPr)₄, Si(OEt)₄, Sn(OBu)₄, SnCl₄, SnBu₂O/acetate, Fe(OEt)₂, Mg(OEt)₂, or CaO;
adding nanocrystals of a photoactive material to the coating composition, comprising at least one of TiO₂, WO₃, Fe₂O₃, and CuO; and
applying the mixture of coating composition and photoactive material to a surface of a substrate, comprising at least one of glass, ceramic, metal, or plastic, wherein one of a) the substrate is provided at an elevated temperature from about 80° C. to about 700° C. prior to the application of the mixture, and b) the mixture is subjected to an elevated temperature from about 80° C. to about 700° C. following the application of the mixture, to deposit a self-cleaning coating on the surface of the substrate.

16. The renewable energy conversion device of claim 15, wherein the device is one of a solar thermal device and a photovoltaic device.
